(19) United States
(12) Patent Application Publication
(10) Pub. No.: US 2025/0289215 A1
(43) Pub. Date: Sep. 18, 2025

(54) METHOD FOR ATTACHING AND DETACHING WAFERS DURING INTEGRATED CIRCUIT MANUFACTURING

(71) Applicant: PulseForge Inc., Austin, TX (US)

(72) Inventors: VIKRAM SHREESHAIL TURKANI, Austin (IN); JONATHAN WILLIAM GIBSON, Steamboat Springs, CO (US)

(73) Assignee: PulseForge Inc., Austin, TX (US)

(21) Appl. No.: 18/605,697

(22) Filed: Mar. 14, 2024

(51) Int. Cl. B32B 43/00; B32B 37/12; H01L 21/683

(52) U.S. Cl. CPC B32B 43/006; B32B 37/12; H01L 21/6836

(57) ABSTRACT

A method for attaching and detaching wafers during integrated circuit manufacturing is disclosed. Initially, a reusable carrier is formed by depositing a layer of partially transparent light-absorbing material (LAM) on a transparent carrier. An ultraviolet (UV) curable adhesive is deposited on a wafer. The wafer is then placed on the reusable carrier with the partially transparent LAM layer in contact with the UV-curable adhesive to form a carrier stack. Next, an UV light is directed through the transparent carrier and the partially transparent LAM layer in order to cure the UV-curable adhesive. After the wafer has been processed, a light pulse is sent from a flashlamp through the transparent carrier in order to detach the wafer from the transparent carrier.

### TECHNICAL FIELD

The present application relates to integrated circuit manufacturing in general, and, in particular, to a method for attaching and detaching wafers during integrated circuit manufacturing.

### BACKGROUND

During integrated circuit manufacturing, a thinning step is often performed on each semiconductor wafer having integrated circuits in order to reduce the thickness of the semiconductor wafer. The semiconductor wafer is typically bonded to a rigid carrier prior to the thinning process. Existing approaches for attaching a semiconductor wafer to a carrier involve the usage of an adhesive placed directly between the semiconductor wafer and the carrier. After back-grinding and all the required backside processing have been completed on the semiconductor wafer, the thinned semiconductor wafer is then detached from the carrier so that it can progress to its next intended destination.

The present disclosure provides an improved method for attaching and detaching substrates during integrated circuit manufacturing.

### SUMMARY OF THE INVENTION

In accordance with one embodiment, a reusable carrier is initially formed by depositing a layer of partially transparent light-absorbing material (LAM) on a transparent carrier. An ultraviolet (UV) curable adhesive is deposited on a wafer. The wafer is then placed on the reusable carrier with the partially transparent LAM layer in contact with the UV-curable adhesive to form a carrier stack. Next, a UV light is directed through the transparent carrier and the partially transparent LAM layer in order to cure the UV-curable adhesive. After the wafer has been processed, a light pulse is sent from a flashlamp through the transparent carrier to detach the wafer from the transparent carrier.

All features and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 is a flow diagram of a method for forming a reusable carrier, according to one embodiment;

FIG. 1A is a diagram of a reusable carrier made by the method depicted in FIG. 1;

FIG. 2 is a flow diagram of a method for attaching and detaching a wafer from a carrier, according to one embodiment;

FIG. 2A is a diagram of a carrier stack made by the method depicted in FIG. 2;

FIG. 2B shows the reusable carrier being released from the wafer from FIG. 2A;

FIG. 3 is a block diagram of an apparatus for attaching and detaching a wafer from a carrier, according to one embodiment; and

FIG. 4 illustrates a vacuum table holding down a carrier stack, according to one embodiment.

### DETAILED DESCRIPTION OF A PREFERRED EMBODIMENT

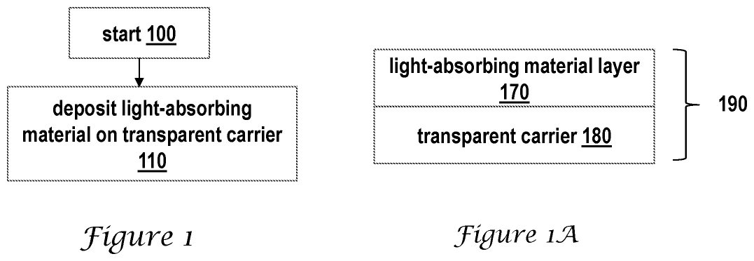

Before any attaching (bonding) and detaching (debonding) of wafers can be performed, a reusable carrier needs to be made for such a purpose. Referring now to the drawings, and in particular to FIG. 1, there is depicted a flow diagram of a method for forming a reusable carrier, according to one embodiment. Starting at block 100, a layer 170 of partially transparent light-absorbing material (LAM) is deposited on a transparent carrier 180, as shown in block 110. Transparent carrier 180 is preferably rigid and is thermally stable beyond 400° C. In addition, transparent carrier 180 is preferably transparent to most (e.g., greater than 50%) of the light emitted by a flashlamp that is a broadband emission from 200 nm to 1,100 nm. Transparent carrier 180 can be round or in the form of a rectangular panel, etc. Transparent carrier 180 can be made of glass. Examples of glass include Eagle XG glass made by Corning, Inc. or D263 glass made by Schott Glass, Inc. Transparent carrier 180 may also made of quartz or a ceramic material such as an oxide, nitride, or carbide, or a high-temperature polymer.

LAM layer 170 can be deposited on transparent carrier 180 via a variety of additive techniques, including thermal evaporation, sputtering, CVD, PECVD, ALD, or other vacuum techniques. It may also be deposited with wet processing techniques such as spin coating, printing, etc. Transparent carrier 180 and LAM layer 170 together formed a reusable carrier 190, as shown in FIG. 1A. LAM layer 170 is approximately 1 to 2,000 nm thick and can transmit 0.1% to 20% of light within a wavelength range of 150 nm to 1,500 nm, which includes ultra-violet (UV) light. LAM layer 170 may include metals (such as tungsten, titanium, molybdenum, niobium, etc.), metal alloys (such as titanium-tungsten), ceramics (such as oxides, nitrides, and carbides) polymers and other materials including carbon (such as amorphous carbon, diamondlike carbon, graphene, etc.). LAM layer 170 is preferably made of a high-temperature material that is stable at a temperature beyond 400° C. In addition, LAM layer 170 has a coefficient of thermal expansion (CTE) within 9×10⁻⁶° C.⁻¹ of the material of transparent carrier 180. Importantly, LAM layer 170 is partially transparent to light, including UV light, but is capable of absorbing some of the light emitted by a flashlamp. LAM layer 170 can transmit 0.1% to 20% of light within a wavelength range of 150 to 500 nm.

After reusable carrier 190 has been made, reusable carrier 190 can be utilized to attach to a wafer with an adhesive disposed between them in order to process the wafer. After the wafer processing has been completed, reusable carrier 190 is detached from the wafer. Reusable carrier 190 can then be cleaned and be utilized again for another wafer.

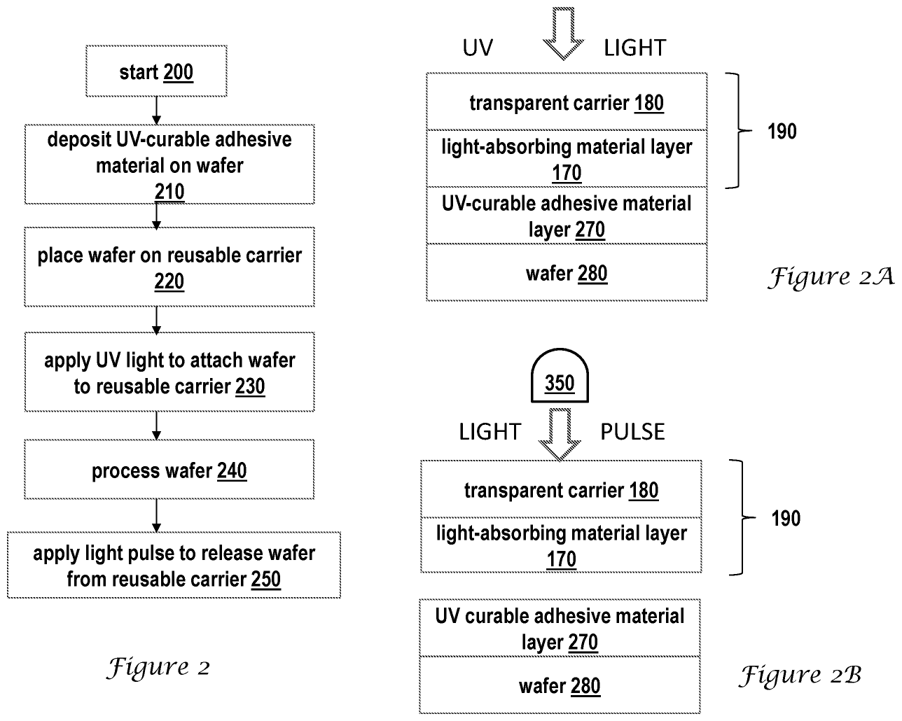

With reference now to FIG. 2, there is depicted a method for attaching reusable carrier 190 to a wafer and for detaching reusable carrier 190 from the wafer, according to one embodiment. Like reusable carrier 190, the wafer can be round or in the form of a rectangular panel, etc. The wafer may be a semiconductor, such as silicon or gallium arsenide. The wafer may also be glass, quartz, ceramic, polymer, or a composite structure.

Starting at block 200, a layer 270 of UV-curable adhesive is disposed on a wafer 280, as shown in block 210. Next, wafer 280 is placed on reusable carrier 190, as depicted in block 220, such that UV-curable adhesive layer 270 comes into contact with LAM layer 170 in order to form a carrier stack, as shown in FIG. 2A. Alternatively, UV-curable adhesive can be disposed on LAM layer 170 of reusable carrier 190 and wafer 280 can then be placed on the UV-curable adhesive in order to form a carrier stack. UV-curable adhesive 270 may be deposited on wafer 280 using a variety of techniques. This includes directly depositing in liquid form onto reusable carrier 190 or wafer 280 using spin coating, casting, etc. After coating UV-curable adhesive layer 270, a drying step may also follow to remove excess solvent prior to placing reusable carrier 190 and wafer 280 adjacent to each other. UV-curable adhesive layer 270 may also be a multilayer UV-curable adhesive layer. This may be cast separately in the form of a self-supporting film before being applied directly to either reusable carrier 190 or wafer 280 and prior to placing them adjacent to each other. In that case, UV-curable adhesive layer 270 may be composed of two layers of UV-curable adhesive with an additional polymeric layer disposed between them to maintain dimensional stability of the self-supporting adhesive film. In the case of a multilayer UV-curable adhesive, it is required that each layer, including the central polymeric layer, is at least partially transparent to the curing light. This is because the UV-curing is performed from one side of a carrier stack. So in order to cure all the layers, each layer must be at least partially transparent to the UV-curing source.

In order to cure UV-curable adhesive layer 270, UV light from a UV source is directed from the side of transparent carrier 180 through LAM layer 170, as shown in block 230. The UV light can be light between 150 nm and 500 nm. The source of UV light can be a light-emitting diode, a mercury arc lamp, an excimer lamp, a flashlamp, etc. At this point, reusable carrier 190 is adhered to wafer 280, as depicted in FIG. 2A.

After wafer 280 has been secured to reusable carrier 190, the back-side of wafer 280 can be processed, as depicted in block 240. The processing may include wafer thinning, redistribution layer (RDL) buildup, deep reactive ion etching (DRIE), photolithography, sputtering, via formation, plating, device building, etc.

After all the wafer processing has been completed on wafer 280, wafer 280 is now ready to be detached (debonded) from reusable carrier 190 (which includes transparent carrier 180 and LAM layer 170). As such, a light pulse is sent from a flashlamp 300 from the side of transparent carrier 180 to heat up LAM layer 170 in order to detach wafer 280 from reusable carrier 190, as shown in block 250.

As shown in FIG. 2B, reusable carrier 190 (which includes transparent carrier 180 and LAM layer 170) is detached from wafer 280. Reusable carrier 190 is then cleaned and is ready to be reused again. In other words, transparent carrier 180 along with LAM layer 170 are reusable.

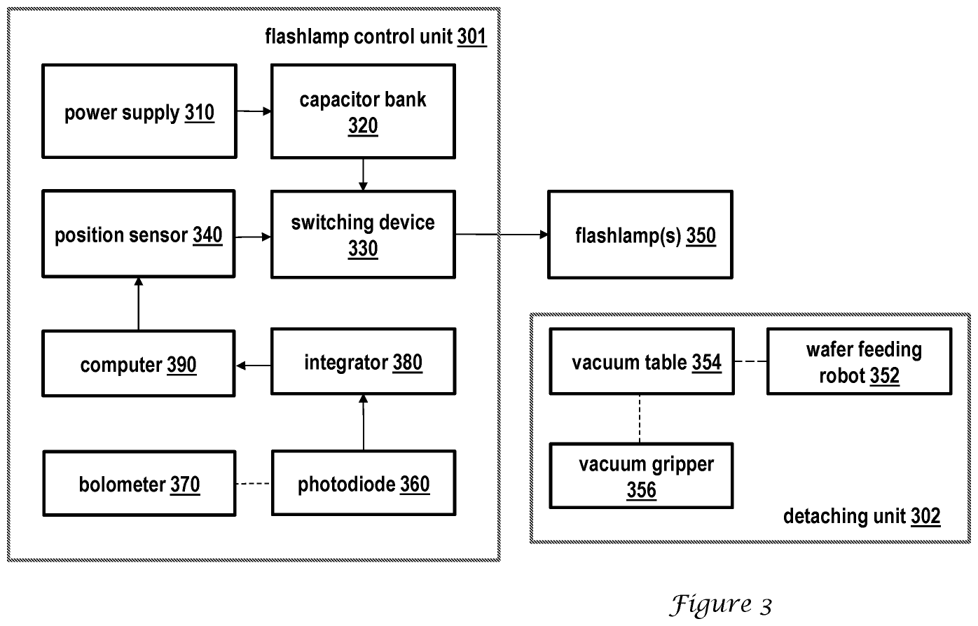

Referring now to FIG. 3, there is depicted a block diagram of an apparatus for performing detachment of a wafer from a carrier, according to one embodiment. As shown, an apparatus 300 includes a flashlamp control unit 301 and detaching unit 302. Flashlamp control unit 301 includes a capacitor-bank-charging power supply 310, a capacitor bank 320, an insulated gate barrier transistor (IGBT)-based switching device 330, a position sensor 340, a photodiode 360, a bolometer 370, an integrator 380, and a computer 390. Computer 390 includes a processor and various storage devices that are well-known to those skilled in the art. The capacitors in capacitor bank 320 are, for example, electrolytic capacitors. The capacitors in capacitor bank 320 may also be pulse discharge capacitors. Capacitor bank 320 may alternatively be switched with a silicon-controlled rectifier (SCR) switching device.

Capacitor bank 320 can be charged by capacitor-bank-charging power supply 310. Current from capacitor bank 320 is then discharged into flashlamp 350 via IGBT-based switching device 330 while IGBT-based switching device 330 is being switched on-and-off by position sensor 340 during the discharge. Position sensor 340 controls the gating of IGBT-based switching device 330 that, in turn, controls the switching of the discharge. The on-and-off switching of IGBT-based switching device 330 is intended to modulate the current flow from capacitor bank 320 to flashlamp(s) 350, which in turn switches flashlamp(s) 350 on-and-off. In other words, the switching of light pulses emitted by flashlamp(s) 350 is dictated by position sensor 340.

If the area of flashlamp illumination is smaller than the size of carrier stack, multiple exposures of light pulse are needed to debond the entire wafer. In that case, the flashlamp head may be indexed relative to the carrier stack to illuminate a portion of the carrier stack until the entire carrier stack has been exposed. The conveyance may be in two dimensions (e.g., x-y) to cover the entire bonded wafer stack and the illuminations may be somewhat overlapped. For example, in the case when the flashlamp illumination area is approximately 75 mm×150 mm, 18-23 pulses of light may be needed to debond a 300 mm diameter wafer, but only 2 pulses of light may be needed to debond a 100 mm wafer.

Detaching unit 302 includes a wafer feeding robot 352, a vacuum table 354, and a vacuum gripper 356.

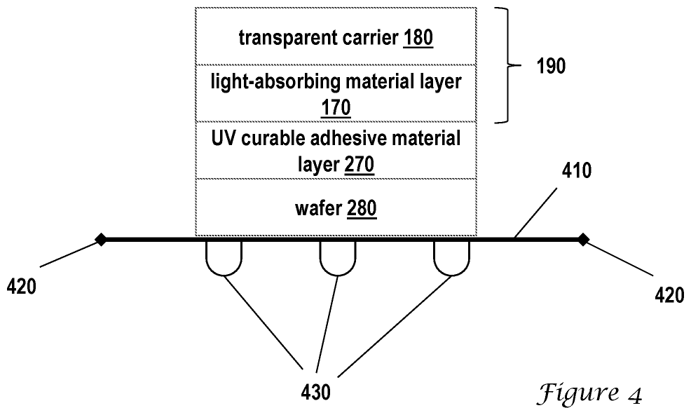

Prior to detaching, a dicing tape 410 may be attached to bonded wafer stack with film frame 420 to form a bonded wafer assembly, as shown in FIG. 4. Wafer feeding robot 352 conveys the bonded wafer assembly to vacuum table 354. A vacuum is then applied on dicing tape 410 from vacuum table 354. Then, a light pulse from flashlamp 350 is utilized to illuminate the bonded wafer assembly from the side of transparent carrier 180 in order to detach processed wafer 280 from transparent carrier 180.

At the separation station, vacuum gripper 356 separates reusable carrier 190 from the bonded wafer assembly, while wafer 280 mounted on dicing tape 410 is being held down by vacuum table 354. Both reusable carrier 190 and wafer 280 on dicing tape 410 are conveyed to a cleaning station to remove any residual adhesive. Residual adhesive may be removed with a wet process via solvent or a dry process with plasma and/or may be peeled off mechanically.

At this point, wafer 280 is so fragile that the vacuum being applied to wafer 280 should be distributed across wafer 280 so as not to break it during removal. This may be accomplished with multiple suction cups 430 distributed across the surface of wafer 280, as depicted in FIG. 4. Alternatively, the vacuum may be applied by a distributed vacuum, such as a vacuum table with perforated holes. Vacuum table 354 may have a polymer on its surface so that wafer 280 is not damaged during handling. As an alternative to a vacuum table and a vacuum gripper, an electrostatic chuck and electrostatic gripper may be used instead.

As has been described, the present invention provides a method for bonding and debonding wafers during integrated circuit manufacturing. One novelty of the present invention is that the LAM layer is reusable. Another novelty of the present invention is that a UV-curable material can be cured through the LAM layer. One advantage of the present invention is that the partial transparency of the LAM layer allows the ability to carefully align the reusable carrier and the wafer relative to each other.

While the invention has been particularly shown and described with reference to a preferred embodiment, it will be understood by those skilled in the art that various changes in form and detail may be made therein without departing from the spirit and scope of the invention.

What is claimed is:

1. A method for attaching and detaching wafers, said method comprising:
forming a reusable carrier by depositing a layer of partially transparent light-absorbing material (LAM) on a transparent carrier;
disposing a UV light-curable adhesive on a wafer;
placing said wafer on said reusable carrier with said partially transparent LAM layer in contact with said UV light-curable adhesive to form a carrier stack;
directing a UV light through said transparent carrier and said partially transparent LAM layer in order to cure said UV light-curable adhesive;
processing said wafer;
sending a light pulse through said transparent carrier to facilitate separation of said wafer from said transparent carrier.

2. The method of claim 1, wherein said transparent carrier is quartz, glass, ceramic, or

3. The method of claim 1, wherein said partially transparent LAM layer includes metal, metal alloy, ceramic carbon, or polymer.

4. The method of claim 3, wherein said ceramic includes oxides, nitrides, or carbides.

5. The method of claim 1, wherein said wafer is made of semiconductor, glass, or polymer.

6. The method of claim 1, wherein said forming a reusable carrier further includes depositing said LAM layer on said transparent carrier via a vacuum deposition or a wet deposition process.

7. The method of claim 1, wherein said sending a light pulse further includes sending a light pulse from a flashlamp through said transparent carrier.

8. The method of claim 1, wherein said method further includes cleaning said reusable carrier and said partially transparent LAM on said transparent carrier for future use.

9. A method for attaching and detaching wafers, said method comprising:
forming a reusable carrier by depositing a layer of partially transparent light-absorbing material (LAM) on a transparent carrier;
disposing a light-curable adhesive on said partially transparent LAM layer on said transparent carrier;
placing a wafer on said light-curable adhesive to form a carrier stack;
directing a light through said transparent carrier and said partially transparent LAM layer in order to cure said light-curable adhesive;
processing said wafer;
sending a plurality of light pulses through said transparent carrier to detach said wafer from said transparent carrier.

10. The method of claim 9, wherein said transparent carrier is quartz, glass, ceramic, or polymer.

11. The method of claim 9, wherein said partially transparent LAM layer includes metal, ceramic, carbon, or polymer.

12. The method of claim 9, wherein said wafer is made of semiconductor, glass, or polymer.

13. The method of claim 9, wherein said light-curable adhesive is a UV light-curable adhesive, and said directing further includes directing a UV light through said transparent carrier.

14. The method of claim 9, wherein said forming a reusable carrier further includes depositing said LAM layer on said transparent carrier via a vacuum deposition or a wet deposition process.

15. The method of claim 9, wherein said sending a light pulse further includes sending a light pulse from a flashlamp through said transparent carrier.

16. The method of claim 9, wherein said method further includes cleaning said reusable carrier and said partially transparent LAM on said transparent carrier for future use.

17. A reusable carrier comprising:
a transparent carrier; and
a layer of partially transparent light-absorbing material (LAM) deposited on said transparent carrier, wherein said partially transparent LAM layer transmits 0.1% to 20% of light within a wavelength range of 150 to 500 nm, wherein said transparent carrier and said partially transparent LAM are cleanable for future usage.

18. The reusable carrier of claim 17, wherein said transparent carrier is quartz, glass or polymer.

19. The reusable carrier of claim 17, wherein said partially transparent LAM layer includes metal, ceramic, carbon or polymer.

20. The method of claim 17, wherein said partially transparent LAM layer is stable at a temperature beyond 400° C. and has a coefficient of thermal expansion that is within 9×10⁻⁶° C.⁻¹ of said transparent carrier.
